(19) United States
(12) Patent Application Publication
(10) Pub. No.: US 2012/0181702 A1
(43) Pub. Date: Jul. 19, 2012

(54) PHOTOSENSITIVE ADHESIVE COMPOSITION HAVING ALKALI SOLUBLE EPOXY RESIN, AND PATTERNABLE ADHESIVE FILM USING THE SAME

(75) Inventors: Jae Jun LEE, Suwon-si (KR); Joon Yong PARK, Suwon-si (KR); Chul Ho JEONG, Gwangju (KR); Yong Seok HAN, Anyang-si (KR)

(73) Assignee: SAMSUNG ELECTRONICS CO., LTD., Suwon-si (KR)

(21) Appl. No.: 13/224,636

(22) Filed: Sep. 2, 2011

(30) Foreign Application Priority Data
Jan. 13, 2011 (KR) 10-2011-0003520

(51) Int. Cl. H01L 23/538; G03F 7/028

(52) U.S. Cl. 257/774; 430/280.1; 257/E23.174

(57) ABSTRACT

Provided are a photosensitive adhesive composition having an alkali soluble epoxy resin and a patternable adhesive film using the same. The photosensitive adhesive composition has good pattern formability and adhesiveness since the photosensitive adhesive composition includes the alkali soluble epoxy resin.

### CROSS-REFERENCE TO RELATED APPLICATION

This application claims priority to Korean Patent Application No. 10-2011-0003520, filed on Jan. 13, 2011, and all the benefits accruing therefrom under 35 U.S.C. §119, the content of which in its entirety is herein incorporated by reference.

### BACKGROUND

1. Field

This disclosure relates to an alkali soluble epoxy resin, a photosensitive adhesive composition including the same, and a patternable adhesive film using the photosensitive adhesive composition.

2. Description of the Related Art

In recent years, various semiconductor packages have been developed to provide improved semiconductor device integration and capacity. In a semiconductor package, an adhesive film is used to adhere a semiconductor device to a supportive substrate.

The adhesive film has excellent thickness and protrusion control capacity when compared to a commercially available paste adhesive. Accordingly, the adhesive film is widely used in high-density semiconductor packages, such as a chip-size package, a stack package, or a system-in-package.

To use a patternable adhesive film in a semiconductor package, the adhesive film desirably has good pattern formability and adhesiveness. Therefore there remains a need for an adhesive composition which can provide an improved patternable adhesive film.

### SUMMARY

A photosensitive adhesive composition having good adhesiveness and pattern formability, and a patternable adhesive film using the same are disclosed.

In an aspect, disclosed is a photosensitive adhesive composition including an alkali soluble epoxy resin, a binder resin, a radical polymerizable (meth)acrylate monomer, a photopolymerization initiator, and a solvent, wherein the alkali soluble epoxy resin comprises a copolymer of at least one selected from a maleimide compound, and a maleic anhydride compound, and at least one selected from a (meth)acrylate monomer including an epoxy group, and a vinyl monomer having an epoxy group.

In another aspect, a patternable adhesive film including a product of the photosensitive adhesive composition disclosed above is provided.

In another aspect, a through-silicon-via (“TSV”)-type semiconductor package including the patternable adhesive film disclosed above interposed between first and second semiconductor wafers is provided.

### BRIEF DESCRIPTION OF THE DRAWINGS

The above and other aspects, advantages and features of this invention will beconie more apparent by describing in further detail exemplary embodiments thereof with reference to the accompanying drawings, in which:

FIG. 1 is a graph of intensity (arbitrary units) versus chemical shift (parts per million versus tetramethylsilane) which shows nuclear magnetic resonance (“NMR”) results of an epoxy resin according to Example 1;

FIG. 2 is a graph of weight (percent) versus temperature (° C.) which shows thermogravimetric analysis (“TGA”) results of the epoxy resin according to Example 1; and

FIG. 3 is a graph of heat flow (watts per gram, W/g) versus temperature (° C.) which shows differential scanning calorimetry (“DSC”) results of the epoxy resin according to Example 1.

### DETAILED DESCRIPTION

The invention now will be described more fully hereinafter with reference to the accompanying drawings, in which a non-limiting embodiment is shown. This invention may, however, be embodied in many different forms, and should not be construed as limited to the embodiment set forth herein. Rather, the disclosed embodiment is provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third, etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the invention.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises” and/or “comprising,” or “includes” and/or “including” when used in this specification, specify the presence of stated regions, integers, steps, operations, elements, and/or components, but do not preclude the presence or addition of one or more other regions, integers, steps, operations, elements, components, and/or groups thereof.

Furthermore, relative terms, such as “lower” or “bottom” and “upper” or “top,” may be used herein to describe one element's relationship to another element as illustrated in the figures. It will be understood that relative terms are intended to encompass different orientations of the device in addition to the orientation depicted in the figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

One or more embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear portions. Moreover, sharp angles that are illustrated may be rounded. Thus, the regions illustrated in the figures are schematic in nature and their shapes are not intended to illustrate the precise shape of a region and are not intended to limit the scope of the claims.

“Hydrocarbon” means an organic compound having at least one carbon atom and at least one hydrogen atom, optionally substituted with one or more substituents where indicated.

“Alkyl” means a straight or branched chain, saturated, monovalent hydrocarbon group (e.g., methyl or hexyl).

“Aryl” means a monovalent group formed by the removal of one hydrogen atom from one or more rings of an arene (e.g., phenyl or napthyl).

“Alkoxy” means an alkyl group that is linked via an oxygen (i.e., alkyl-O—), for example methoxy, ethoxy, and sec-butyloxy groups.

“Aryloxy” means an aryl moiety that is linked via an oxygen (i.e., —O-aryl).

“Cycloalkene” means a compound having one or more rings and one or more carbon-carbon double bond in the ring, wherein all ring members are carbon (e.g., cyclopentane and cyclohexane).

“Halogen” means one of the elements of group 17 of the periodic table (e.g., fluorine, chlorine, bromine, iodine, and astatine).

A (meth)acrylate group is inclusive of an acrylate (H₂C═CH—C(═O)O—) group or a methacrylate group (H₂C═C(CH₃)—C(═O)O—).

A (meth)acryloyl group is inclusive of an acryloyl group (H₂C═CH—C(═O)—) or a methacryloyl group (H₂C═C(CH₃)—C(═O)—).

“Substituted” means that the compound or group is substituted with at least one (e.g., 1, 2, 3, or 4) substituent independently selected from a hydroxyl (—OH), a nitro (—NO₂), a cyano (—CN), an amino (—NH₂), a carbamoyl group (—C(O)NH₂), a thiol (—SH), a thiocyano (—SCN), a tosyl (CH₃C₆H₄SO₂—), a carboxylic acid (i.e., a carboxyl group, —C(═O)OH), a carboxylic acid salt (—C(═O)OM) wherein M is an organic or inorganic anion, a sulfonic acid (—SO₃H₂), a sulfonic mono- or dibasic salt (—SO₃ MH or —SO₃M₂ wherein M is an organic or inorganic anion), a phosphoric acid (—PO₃H₂), and a phosphoric acid mono- or dibasic salt (—PO₃ MH or —PO₃M₂ wherein M is an organic or inorganic anion), instead of hydrogen, provided that the substituted atom's normal valence is not exceeded.

In an aspect, a photosensitive adhesive composition comprises an alkali soluble epoxy resin, a binder resin, a radical polymerizable (meth)acrylate monomer, a photopolymerization initiator, and a solvent.

The alkali soluble epoxy resin may be a copolymer of at least one selected from a maleimide compound, and a maleic anhydride compound; and at least one selected from a (meth)acrylate monomer comprising an epoxy group, and a vinyl monomer comprising an epoxy group.

Also, the alkali soluble epoxy resin may be a copolymer of at least one selected from a maleimide compound and a maleic anhydride compound, and at least one selected from a (meth)acrylate monomer comprising an epoxy group, a vinyl monomer comprising an epoxy group, wherein the maleimide compound and the maleic anhydride compound may be a C₄ to C₂₀ cycloalkene derivative. The maleimide compound may be a maleimide in which a nitrogen of the maleimide is substituted or unsubstituted. While not wanting to be bound by theory, it is understood that the maleimide group may improve a heat resistance of a patternable adhesive film.

For example, the nitrogen of the maleimide compound may be substituted with a phenyl group substituted with at least one selected from a carboxyl group and a hydroxyl group. While not wanting to be bound by theory, it is understood that the phenyl group substituted with the carboxyl group or the hydroxyl group may render the epoxy resin soluble in alkali and may improve developing properties of the patternable adhesive film.

When the nitrogen of the maleimide compound is substituted with a phenyl group substituted with at least one hydroxyl group, the alkali soluble epoxy resin may be prepared by further contacting (e.g., reacting) a (meth)acrylate monomer comprising an isocyanate group and at least one (meth)acryloyl group. For example, an alkali soluble epoxy resin comprising a (meth)acrylate partially contained in a side chain thereof may be prepared by urethane reaction of the isocyanate group with the hydroxyl group of the phenyl group. The (meth)acrylate monomer comprising an isocyanate group and a (meth)acryloyl group may have a structure represented by the following Formula 1.

CH₂═CR—C(═O)O—(CH₂)ₘ—NCO Formula 1

In Formula 1, m is an integer of 1 to 10, or 1 to 8, or 2 to 6, and R is hydrogen or a methyl group.

Also, the maleimide compound may have a structure in which a C₄ to C₂₀ cycloalkene is fused to a maleimide. For example, the maleimide compound may be at least one selected from the following Formulas 2-1 and 2-2, but is not limited thereto.

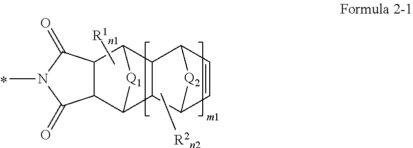

In Formula 2-1, n₁ and n₂ are each independently an integer of 0 to 6,
each R¹ and R² is independently selected from hydrogen, halogen, a substituted or unsubstituted C₁ to C₂₀ alkyl group, a substituted or unsubstituted C₁ to C₂₀ alkoxy group, a substituted or unsubstituted C₆ to C₃₀ aryl group, and a substituted or unsubstituted C₆ to C₃₀ aryloxy group, provided that each R¹ and R² may independently be the same or different, thus each R¹ and R² may independently be different when n₁ or n₂ is 2 or more,
each Q₁ and Q₂ is independently selected from a methylene group, O and S, and
m₁ is an integer of 0 to 2.

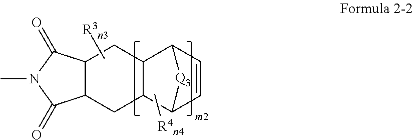

In Formula 2-2, n₃ is an integer of 0 to 8, and n₄ is an integer of 0 to 6,
each R³ and R⁴ is independently selected from hydrogen, halogen, a substituted or unsubstituted C₁ to C₂₀ alkyl group, a substituted or unsubstituted C₁ to C₂₀ alkoxy group, a substituted or unsubstituted C₆ to C₃₀ aryl group, and a substituted or unsubstituted C₆ to C₃₀ aryloxy group, provided that each R³ and R⁴ may be the same or different, thus each R³ and R⁴ may be different when each n₃ and n₄ is 2 or more,
Q₃ is selected from a methylene group, O and S, and
m₂ is an integer of 0 to 2.

The maleic anhydride compound may be maleic anhydride, or a maleic anhydride to which at least one C₄ to C₂₀ cycloalkene is fused. For example, the maleic anhydride compound may be at least one selected from the following Formulas 3-1 and 3-2, but is not limited thereto.

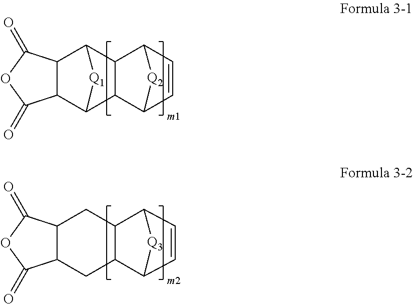

In Formulas 3-1 and 3-2, Q₁, Q₂, Q₃, m₁ and m₂ are as defined in Formulas 2-1 and 2-2.

In an embodiment, an alkali soluble epoxy resin having a carboxylic group and a (meth)acrylic group may be prepared by addition reaction of the epoxy resin having the maleic anhydride with a (meth)acrylate monomer having a hydroxyl group and at least one (meth)acryloyl group. During the addition reaction, the maleic anhydride reacts with the (meth)acrylate monomer having a hydroxyl group, and a ring of the maleic anhydride opens, and thereby creating the carboxylic acid group. The carboxylic acid group may render the epoxy resin soluble in alkali and may improve developing properties of the patternable adhesive film. An example of the ring-opening reaction is shown in the following Scheme 1.

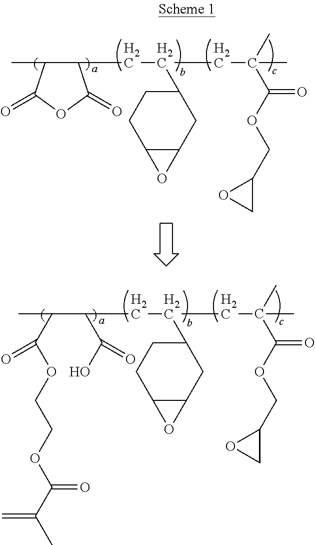

The (meth)acrylate monomer having a hydroxyl group may be represented by the following Formula 4, but is not limited thereto.

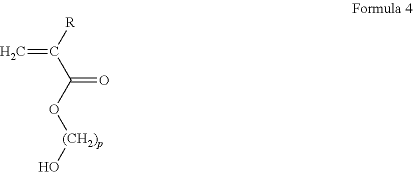

In Formula 4, p is an integer of 1 to 10, and R is hydrogen or a methyl group.

The C₄ to C₂₀ cycloalkene may be a cycloalkene containing a double bond within the cyclic moiety and/or having a vinyl substituent.

The cycloalkene may have a structure in which one or more C₄ to C₂₀ cycloalkenes are fused or coupled with each other. For example, the C₄ to C₂₀ cycloalkene may be at least one selected from 2-norbornene, 5-vinyl-2-norbornene, bicyclo[2.2.1]hepta-2,5-diene, dicyclopentadiene, and a cyclohexene compound, but is not limited thereto.

The (meth)acrylate monomer having an epoxy group may be a (meth)acrylate monomer having an epoxy group at an end of the monomer. In the patternable adhesive film, and while not wanting to be bound by theory, the epoxy group may provide improved adhesiveness to a wafer at a high temperature.

For example, the (meth)acrylate monomer having an epoxy group may have a structure represented by the following Formula 5.

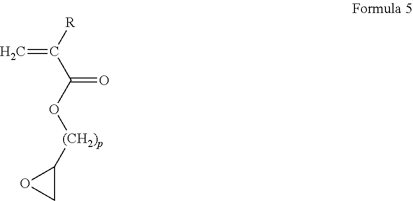

In Formula 5, R is hydrogen or methyl, and n is integer of 1 to 10.

For example, the (meth)acrylate monomer having an epoxy group may be at least one selected from glycidyl (meth)acrylate, 3,4-epoxy-1-cyclohexylmethyl (meth)acrylate, 5,6-epoxy-2-bicyclo[2.2.1]heptyl (meth)acrylate, 5,6-epoxyethyl-2-bicyclo[2.2.1]heptyl (meth)acrylate, 5,6-epoxy-2-bicyclo[2.2.1]heptylmethyl (meth)acrylate, 3,4-epoxytricyclo[5.2.1.0^{2.6}]decyl (meth)acrylate, 3,4-epoxytricyclo[5.2.1.0^{2.6}]decyloxyethyl (meth)acrylate, 3,4-epoxytetracyclo[4.4.0.1^{2.5}.1^{7.10}]dodecyl (meth)acrylate, and 3,4-epoxytetracyclo[4.4.0.1^{2.5}.1^{7.10}]dodecylmethyl (meth)acrylate, but is not limited thereto.

The vinyl monomer having an epoxy group may be a vinyl compound having an epoxy group at an end of the monomer. In the patternable adhesive film, and while not wanting to be bound by theory, the epoxy group may improve adhesiveness to a wafer at a high temperature. Examples of the vinyl monomer may include at least one selected from 4-vinyl-1-cyclohexene-1,2-epoxide, allyl glycidyl ether, and cyclohexane-1,2-epoxide-substituted norbornene, but is not limited thereto.

In the alkali soluble epoxy resin, at least one selected from the maleimide compound and the maleic anhydride compound may be included in an amount of about 10 to about 50 mole percent (mol %), or about 20 to about 35 mol %, or about 25 to about 30 mol %, based on the total moles of monomers used to prepare the epoxy resin. Within the above range, the alkali soluble epoxy resin may have excellent heat resistance and excellent solubility in an alkali developing solution.

In the alkali soluble epoxy resin, the C₄ to C₂₀ cycloalkene compound may be polymerized (e.g., included) in an amount of about 10 to about 40 mol %, or about 20 to about 30 mol %, or about 25 mol %, based on the total moles of the alkali soluble epoxy resin. Within the foregoing range, the adhesive film according to an exemplary embodiment may have excellent heat resistance and thermal stability.

In the alkali soluble epoxy resin, the (meth)acrylate and vinyl monomers having an epoxy group may be polymerized (e.g., included) in an amount of about 30 to about 90 mol %, or about 50 to about 75 mol %, or about 60 to about 70 mol %, based on the total moles of monomers used to prepare the epoxy resin. Within the foregoing range, the adhesive film according to an exemplary embodiment may provide excellent heat resistance and an excellent adhesive force to a wafer.

The alkali soluble epoxy resin may be prepared by a commercially available polymerization method. For example, the alkali soluble epoxy resin may be prepared by a method such as solution polymerization, emulsion polymerization, condensation polymerization, or interfacial polymerization, but is not limited thereto. The polymerization may be performed at a polymerization temperature of 50 to 100° C. and a polymerization time of 1 to 10 hours, but is not limited thereto.

In the polymerization of the alkali soluble epoxy resin, a polymerization initiator may be used to facilitate a polymerization reaction. A commercially available polymerization initiator, for example azobisisobutyronitrile, may be used, but is not limited thereto.

For example, the alkali soluble epoxy resin may be a copolymer of a maleimide compound, a vinyl monomer having an epoxy group, and a (meth)acrylate monomer having an epoxy group. In an embodiment, the alkali soluble epoxy resin may have a structure represented by the following Formula 6.

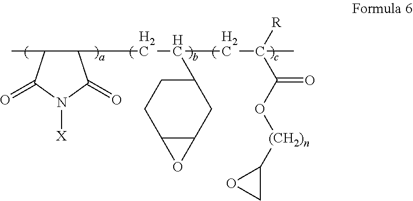

In Formula 6, X is a carboxyl group, or a phenyl group which is substituted with at least one substituent selected from a carboxyl group and a hydroxyl group,
R is hydrogen or methyl,
n is an integer of 1 to 10, and
a, b and c represent a mole fraction of each respective unit, a+b+c=1, a mole fraction ratio a:b:c is 0.1 to 0.5:0 to 0.9:0 to 0.9, b+c>0, and the a, b, and c units may be arranged in any order. In an embodiment the a, b, and c units are arranged in a random order. In another embodiment, the a, b, and c units are arranged in blocks.

For example, the alkali soluble epoxy resin may be a copolymer, which is formed by addition reaction of an acrylate monomer having an acryloyl group and an isocyanate group to a free copolymer of a maleimide monomer, a vinyl monomer having an epoxy group, and a (meth)acrylate monomer having an epoxy group.

According to an exemplary embodiment, the alkali soluble epoxy resin may have a structure represented by the following Formula 7.

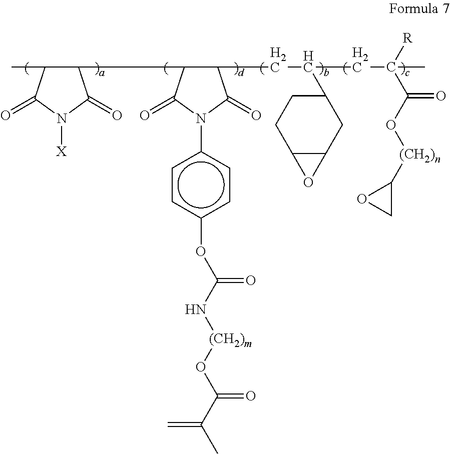

In Formula 7, X is a carboxyl group, or a phenyl group which is substituted with at least one substituent selected from a carboxyl group and a hydroxyl group,
R is hydrogen or methyl,
each n and m is independently an integer of 1 to 10, and
a, b, c, and d represent a mole fraction of each respective unit, a+b+c+d=1, a mole fraction ratio a:b:c:d is 0 to 0.49:0 to 0.9:0 to 0.9:0.01 to 0.5, b+c>0, and the a, b, c, and d units may be arranged in any order. In an embodiment the a, b, and c units are arranged in a random order. In another embodiment, the a, b, and c units are arranged in blocks. In an embodiment, a+d may be 0.1 to 0.5.

For example, the alkali soluble epoxy resin may be a copolymer of a norbornene group-fused maleic anhydride, a maleic anhydride, and a (meth)acrylate monomer having an epoxy group. According to an exemplary embodiment, the alkali soluble epoxy resin may have a structure represented by the following Formula 8.

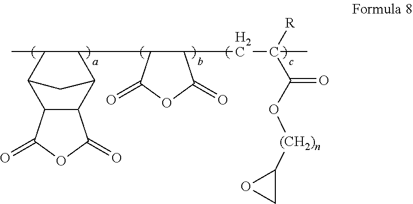

In Formula 8, R is hydrogen or methyl,
n is an integer of 1 to 10, and
a, b, and c represent a mole fraction of each respective unit, a+b+c=1, a mole fraction ratio a:b:c is 0.01 to 0.49:0.01 to 0.49:0.3 to 0.9, and the a, b, and c units may be arranged in any order. In an embodiment the a, b, and c units are arranged in a random order. In another embodiment, the a, b, and c units are arranged in blocks.

For example, the alkali soluble epoxy resin may be a copolymer, which is formed by addition reaction of an acrylate monomer having an acrylic group and an isocyanate group to a free copolymer of a maleimide monomer fused with a norbornene group-fused maleimide monomer, a vinyl monomer having an epoxy group, and a (meth)acrylate monomer having an epoxy group.

According to an exemplary embodiment, the alkali soluble epoxy resin may have a structure represented by the following Formula 9.

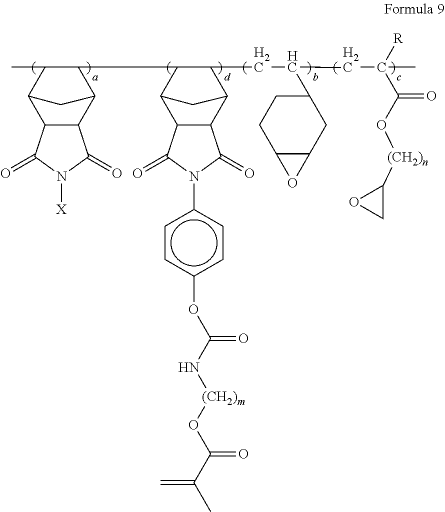

In Formula 9, X is a carboxyl group, or a phenyl group which is substituted with at least one substituent selected from a carboxyl group and a hydroxyl group,
R is hydrogen or methyl,
each n and m is independently an integer of 1 to 10, and
a, b, c, and d represent a mole fraction of each respective unit, a+b+c+d=1, a mole fraction ratio of a:b:c:d is 0 to 0.49:0 to 0.9:0 to 0.9:0.01 to 0.5, b+c>0, and the a, b, c, and d units may be arranged in any order. In an embodiment the a, b, and c units are arranged in a random order. In another embodiment, the a, b, and c units are arranged in blocks. In an embodiment, a+d may be 0.1 to 0.5.

For example, the alkali soluble epoxy resin may be a copolymer of a maleic anhydride compound, a vinyl monomer having an epoxy group, and a (meth)acrylate monomer having an epoxy group. In an exemplary embodiment, the alkali soluble epoxy resin may have a structure represented by the following Formula 10.

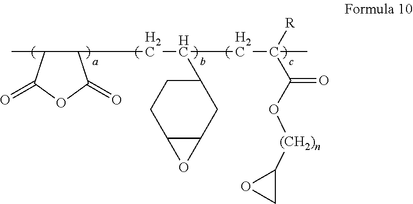

In Formula 10, R is hydrogen or methyl,
n is an integer of 1 to 10, and
a, b, and c represent a mole fraction of each respective unit, a+b+c=1, a mole fraction ratio a:b:c is 0.1 to 0.5:0 to 0.9:0 to 0.9, b+c>0, and the a, b, and c units may be arranged in any order. In an embodiment the a, b, and c units are arranged in a random order. In another embodiment, the a, b, and c units are arranged in blocks.

For example, the alkali soluble epoxy resin may be a copolymer, which is formed by addition reaction of a (meth)acrylic monomer having a hydroxyl group to a pre-copolymer of a maleic anhydride compound, a vinyl monomer having an epoxy group and a (meth)acrylate monomer having an epoxy group. According to an exemplary embodiment, the alkali soluble epoxy resin may have a structure represented by the following Formula 11.

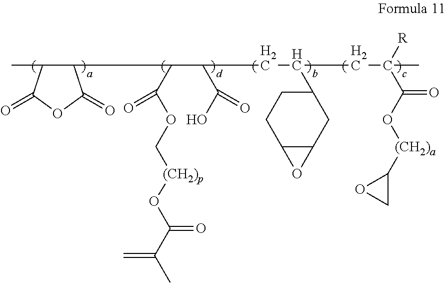

In Formula 11, R is hydrogen or methyl,
each n and p is independently an integer of 1 to 10, and
a, b, c, and d represent a mole fraction of each respective unit, a+b+c+d=1, a mole fraction ratio a:b:c:d is 0 to 0.49:0 to 0.9:0 to 0.9:0.01 to 0.5, b+c>0, and the a, b, c, and d units may be arranged in any order. In an embodiment the a, b, and c units are arranged in a random order. In another embodiment, the a, b, and c units are arranged in blocks. In an embodiment, a+d may be 0.1 to 0.5.

For example, the alkali soluble epoxy resin may be a copolymer of a maleic anhydride compound, a C₅ to C₂₀ cycloalkene monomer, and a (meth)acrylate monomer having an epoxy group. According to an exemplary embodiment, the epoxy resin may have a structure represented by the following Formula 12.

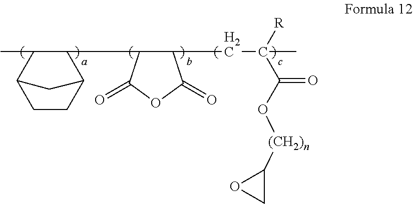

In Formula 12, n is an integer of 1 to 10, R is hydrogen or a methyl group, and a, b, and c represent a mole fraction of each respective unit, a+b+c=1, a mole fraction ratio a:b:c is 0.1 to 0.4:0.1 to 0.4:0.3 to 0.8, and the a, b, and c units may be arranged in any order. In an embodiment the a, b, and c units are arranged in a random order. In another embodiment, the a, b, and c units are arranged in blocks.

In the alkali soluble epoxy resins of Formulas 6 to 12, the monomers may be arranged in any order. In an embodiment the units, e.g., the a, b, and c units and the d unit if present, are arranged in a random order. In another embodiment, the a, b, and c units, and the d unit if present, are arranged in blocks, wherein each block consists of a single type of monomer.

A photosensitive adhesive composition including the alkali soluble epoxy resin is, provided. The photosensitive adhesive composition may include an alkali soluble binder resin, a radical polymerizable (meth)acrylate monomer, the alkali soluble epoxy resin, a photopolymerization initiator, and a solvent.

The photosensitive adhesive composition may include about 40 to about 80% by weight, or about 50 to about 70% by weight, or about 60% by weight of the alkali soluble binder resin, about 1 to about 10% by weight, or 2 to about 9% by weight, or 3 to about 8% by weight of the radical polymerizable (meth)acrylate monomer, about 5 to about 50% by weight, or about 10 to about 45% by weight, or about 10 to about 40% by weight of the alkali soluble epoxy resin, about 1 to about 10% by weight, or about 2 to about 9% by weight, or about 3 to about 8% by weight of the photopolymerization initiator, based on the total weight of the photosensitive adhesive composition, and a solvent, wherein the solvent is included in an amount corresponding to the balance of the composition. In an embodiment, the solvent is included in an amount of about 64 to 1 percent, or about 60 to about 2 percent, or about 50 to about 3%, based on the total weight of the photosensitive adhesive composition.

The alkali soluble binder resin is a thermoplastic and a photocurable resin comprising a carboxyl group, a hydroxyl group, or an aromatic hydroxyl group, and may be soluble in a developing solution. Examples of the alkali soluble binder resin may include

a first carboxyl-group containing resin,

a second carboxyl group-containing resin,

a first carboxyl group-containing urethane resin,

a first carboxyl group-containing polyester resin,

a second carboxyl group-containing polyester resin,

a first carboxyl group-containing photosensitive resin,

a second carboxyl group-containing photosensitive resin,

a carboxyl group-containing photosensitive compound,

a photosensitive carboxyl group-containing urethane resin,

a second carboxyl group-containing urethane resin,

a third carboxyl group-containing urethane resin,

a third carboxyl group-containing photosensitive resin, and

a fourth carboxyl group-containing photosensitive resin.

The first carboxyl group-containing resin may be obtained by copolymerizing an unsaturated carboxylic acid, such as (meth)acrylic acid, and a compound comprising an unsaturated double bond, such as styrene, a-methylstyrene, a lower (e.g., C₁ to C₁₀ alkyl(meth)acrylate, or isobutylene.

The second carboxyl group-containing resin may be obtained by contacting (e.g., reacting) an organic acid that has carboxyl group, such as an C₂ to C₁₇ alkylcarboxylic acid or an aromatic group-containing alkylcarboxylic acid, wherein the organic acid that has the carboxyl group does not have an ethylenic unsaturated bond, a compound containing an unsaturated double bond, and an epoxy group of a glycidyl(meth)acrylate copolymer, and by contacting (e.g., reacting) a saturated or unsaturated polybasic acid anhydride with a resulting secondary hydroxyl group.

The first carboxyl group-containing urethane resin may be obtained by addition reaction of a diisocyanate, such as an aliphatic diisocyanate, a branched aliphatic diisocyanate, an alicyclic diisocyanate, or an aromatic diisocyanate, a carboxyl group-containing diol compound, such as dimethylolpropionic acid or dimethylolbutyric acid, and a polyol compound such as a polycarbonate polyol, a polyether polyol, a polyester polyol, a polyolefin polyol, an acrylic polyol, a bisphenol A alkylene oxide diol adduct, or a compound comprising a phenolic hydroxyl group and an alcoholic hydroxyl group.

The first carboxyl group-containing polyester resin may be obtained by contacting (e.g., reacting) an unsaturated monocarboxylic acid and a multifunctional oxetane compound comprising at least two oxetane rings, and by contacting (e.g., reacting) a saturated or unsaturated polybasic acid anhydride to a secondary hydroxyl group in a resulting modified oxetane compound.

The second carboxyl group-containing polyester resin may be obtained by contacting (e.g., reacting) a dicarboxylic acid and a difunctional epoxy resin or a difunctional oxetane resin, and by adding a saturated or unsaturated polybasic acid anhydride to the resulting secondary hydroxyl group.

The first carboxyl group-containing photosensitive resin may be obtained by contacting (e.g., reacting) a compound comprising an unsaturated ethylenic group such as a vinyl group, an allyl group or a (meth)acryloyl group and a reactive group such as an epoxy group or an acid chloride, for example glycidyl(meth)acrylate, to a part of a copolymer of an unsaturated carboxylic acid and a compound containing an unsaturated double bond, and by adding an unsaturated ethylenic group as a pendant.

The second carboxyl group-containing photosensitive resin may be obtained by contacting (e.g., reacting) an unsaturated carboxylic acid to a copolymer of a compound comprising an epoxy group and an unsaturated double bond, such as glycidyl(meth)acrylate or a-methylglycidyl(meth)acrylate, and a compound containing an unsaturated double bond, and by contacting (e.g., reacting) a saturated or unsaturated polybasic acid anhydride such as phthalic anhydride, tetrahydrophthalic anhydride or hexahydrophthalic anhydride to the resulting secondary hydroxyl group.

The carboxyl group-containing photosensitive compound may be obtained by completely or partially esterifying a carboxyl group of an unsaturated monocarboxylic acid, such as (meth)acrylic acid, with an epoxy group of a multifunctional epoxy compound comprising at least two epoxy groups or a multifunctional epoxy resin in which a hydroxyl group of a multifunctional epoxy compound is further epoxidized with epichlorohydrin, and by further contacting (e.g., reacting) a saturated or unsaturated polybasic acid anhydride with the resulting hydroxyl group.

The photosensitive carboxyl group-containing urethane resin may be obtained by addition reaction of a diisocyanate, (meth)acrylate, or modified acid anhydride of a difunctional epoxy resin, such as a bisphenol A epoxy resin, a hydrogenated bisphenol A epoxy resin, a brominated bisphenol A epoxy resin, a bisphenol F epoxy resin, a bisphenol S epoxy resin, a bixylenol epoxy resin, or a biphenol epoxy resin, a carboxyl group-containing diol compound, and a diol compound.

The second carboxyl group-containing urethane resin may comprise a double bond introduced to the end thereof, which is obtained by adding a compound comprising a hydroxyl group and containing at least one ethylenic unsaturated double bond, such as hydroxyalkyl(meth)acrylate, during the synthesis of the resin of the carboxyl group-containing resin or the photosensitive carboxyl group-containing urethane resin.

The third carboxyl group-containing urethane resin may be obtained by adding a compound comprising an isocyanate group and at least one (meth)acryloyl group, such as a reaction product of equimolar amounts of isophoronediisocyanate and pentaerythritol triacrylate during the synthesis of the resin of the second carboxyl group-containing resin or the photosensitive carboxyl group-containing urethane resin, and by (meth)acrylating the end of the resulting compound.

The third carboxyl group-containing photosensitive resin may be obtained by introducing an unsaturated double bond into a reaction product of a bisepoxy compound and a bisphenol, and by subsequently contacting (e.g., reacting) a saturated or unsaturated polybasic acid anhydride.

The fourth carboxyl group-containing photosensitive resin may be obtained by contacting (e.g., reacting) an unsaturated monocarboxylic acid and a reaction product of a novolac phenol resin, an alkylene oxide such as ethylene oxide, propylene oxide, butylene oxide, trimethylene oxide, tetrahydrofuran, or tetrahydropyran, and/or a cyclic carbonate such as propylene carbonate, butylene carbonate, or 2,3-carbonatepropyl methacrylate, and by contacting (e.g., reacting) a saturated or unsaturated polybasic acid anhydride with the resulting reaction product.

According to a specific embodiment, the alkali soluble binder resin may be at least one selected from a novolac acrylate oligomer comprising a carboxyl group and an acryloyl group, a urethane acrylate oligomer comprising a carboxyl group and an acryloyl group, and an acrylate polymer having a carboxyl group and an acryloyl group, wherein the alkali soluble binder resin has a glass transition temperature of 50° C. or higher.

The radical polymerizable (meth)acrylate monomer may be a photopolymerizable acrylic monomer comprising at least one acryloyl reactive group. Also, these monomers may serve as not only a diluent to facilitate application of a solution, but also as a reinforcing agent to improve photopolymerizable properties of a resin film when photopolymerized by light exposure after formation of a film through a drying process.

The photopolymerizable acrylic monomer comprising at least one acryloyl reactive group may be at least one selected from a hydroxyalkyl acrylate, such as 2-hydroxyethyl acrylate or 2-hydroxybutyl acrylate, 1,6-hexanediol diacrylate, triethylene glycol diacrylate, trimethylolpropane triacrylate, tetraethylene glycol diacrylate, 1,3-butanediol diacrylate, neopentyl glycol diacrylate, pentaerythritol triacrylate, dipentaerythritol pentaacrylate, dipentaerythritol hexaacrylate, oligoester (meth)acrylate, multifunctional urethane (meth)acrylate, and urea acrylate.

The detailed description of the alkali soluble epoxy resin is as disclosed above and thus is not repeated.

The photopolymerization initiator having a 400-nanometer (nm) absorption band may be used to form a highly precise pattern during ultraviolet (“UV”) exposure. For example, the photopolymerization initiator may be 1-hydroxy-cyclohexyl-phenyl-ketone, 2-hydroxy-2-methyl-1-phenyl-1-propanone, 2-hydroxy-1-[4-(2-hydroxyethoxyl)phenyl]-2-methyl-1-propanone, methylbenzoylformate, α,α-dimethoxy-α-phenylacetophenone, 2-benzyl-2-(dimethylamino)-1-[4-(4-morpholinyl)phenyl]-1-butanone, 2-methyl-1-[4-(methylthio)phenyl]-2-(4-morpholinyl)-1-propanone, diphenyl (2,4,6-trimethylbenzoyl)-phosphine oxide, phosphine oxide, or any combination thereof. The photopolymerization initiators may be used alone or in combination, and in an embodiment two or more may be used together, but are not limited thereto.

A suitable solvent may be selected and used as the solvent to uniformly dissolve and disperse solid components included in the photosensitive adhesive composition. For example, the solvent may include

a ketone, e.g., methyl ethyl ketone, or cyclohexanone,

an aromatic hydrocarbon, e.g., toluene, xylene, or tetramethylbenzene,

a glycolether e.g., methyl cellosolve, ethyl cellosolve, butyl cellosolve, benzyl cellosolve, phenyl cellosolve, methylcarbitol, butylcarbitol, propylene glycol monomethyl ether, dipropylene glycol monomethyl ether, dipropylene glycol monobutyl ether, or triethylene glycol monoethyl ether,

an ester, e.g., an esterification product of ethyl acetate, butyl acetate, or ethyl ethoxy propionate, and a glycol ether, e.g., cellosolve acetate, butyl cellosolve acetate, carbitol acetate, butyl carbitolacetate, or propylene glycol monomethyl ether acetate,

an alcohol, e.g., ethanol, propanol, n-butanol, n-hexanol, n-heptanol, n-octanol, ethylene glycol, or propylene glycol,

an aliphatic hydrocarbon, e.g., octane, or decane, or

a petroleum solvent, e.g., petroleum ether, petroleum naphtha, hydrogenated petroleum naphtha, or solvent naphtha. A combination comprising at least one of the foregoing can be used, and in an embodiment the solvent may be used alone, or two or more may be used together.

A content of the solvent is not especially limited, and the solvent may be added such that solid components in the photosensitive adhesive composition have a concentration of about 20 to about 60% by weight, or about 30 to about 50%, or about 40% by weight, based on the total weight of the photosensitive adhesive composition. Within the above range, the photosensitive adhesive composition may exhibit an excellent film-forming property.

The photosensitive adhesive composition may further include an epoxy resin in addition to the alkali soluble epoxy resin. While not wanting to be bound by theory, it is understood that inclusion of the epoxy resin may improve crosslinking density of the photosensitive adhesive film, thereby improving heat resistance after a curing process, and may also improve fluidity during thermal compression when a viscous liquid epoxy resin is used as the alkali soluble epoxy resin, thereby improving an adhesive bond to a wafer at a high temperature. Also, the photosensitive adhesive film may provide improved developing properties in an alkali developing solution when a liquid epoxy resin is used as the alkali soluble epoxy resin.

Specific examples of the epoxy resin may include at least one selected from a phenol glycidylether epoxy resin, such as

a phenol novolac epoxy resin, a cresol novolac epoxy resin, a naphthol-modified novolac epoxy resin, a bisphenol A novolac epoxy resin, a bisphenol F novolac epoxy resin, a biphenyl epoxy resin, a triphenyl epoxy resin, a terpene epoxy resin, or a phenyl aralkyl epoxy resin,

a dicyclopentadiene epoxy resin comprising a dicyclopentadiene backbone,

a bisphenol A epoxy resin, a bisphenol F epoxy resin,

a naphthalene epoxy resin comprising a naphthalene backbone,

a dihydroxy benzopyran epoxy resin,

a glycidyl amine epoxy resin derived from a polyamine such as diaminophenylmethane,

a triphenolmethane epoxy resin, a tetraphenylethane epoxy resin,

bisphenol A diglycidyl ether, bisphenol A bis(triethylene glycol glycidylether), 1,4-cyclohexane dimethanol diglycidyl ether, 1,2-diglycidyl cyclohexane dicarboxylate, or 3,4-epoxycyclohexylmethyl 3,4-epoxycyclohexane carboxylate, but is not limited thereto.

The photosensitive adhesive composition may further include at least one selected from a curing agent, a curing accelerator, a catalyst, a photoacid generator, a coupling agent, and a filler.

The curing agent may comprise a phenol compound, an aliphatic amine, an alicyclic amine, an aromatic polyamine, a polyamide, an aliphatic acid anhydride, an alicyclic acid anhydride, an aromatic acid anhydride, a dicyano diamide, a boron trifluoride-amine complex, an imidazole, or a tertiary amine. A combination comprising at least one of the foregoing can be used. Alternatively, the curing agent may comprise a phenol compound comprising at least two hydroxyl groups, which, while not wanting to be bound by theory, may provide desirable developing properties in an organic solvent. For example, the curing agent may comprise a phenol novolac resin, a cresol novolac resin, a t-butyl phenol novolac resin, a xylene-modified novolac resin, a naphthol novolac resin, a trisphenol novolac resin, a tetrakis phenol novolac resin, a bisphenol-A novolac resin, a poly-p-vinyl phenol resin, a phenol aralkyl resin, or a trisphenol compound. A combination comprising at least one of the foregoing can be used.

The curing accelerator or catalyst are not especially limited, provided that they may promote the curing of the epoxy resin. For example, the curing accelerator or catalyst may be an imidazole, a dicyandiamide compound, dicarboxylic acid dianhydride, triphenyl phosphine, tetraphenyl phosphonium tetraphenylborate, or 2-ethyl-4-methyl imidazole-tetra phenylborate. A combination comprising at least one of the foregoing can be used.

The photoacid generator may generate an acid during UV irradiation to partially cure the epoxy resin. The photoacid generator may comprise an aromatic iodonium salt or an aromatic sulfonium salt. For example, the photoacid generator may comprise di(t-butylphenyl)iodonium triplate, diphenyliodonium tetrakis(pentafluorophenyl)borate, diphenyliodonium hexafluorophosphate, diphenyliodonium hexafluoro antimonate, di(4-nonylphenyl)iodonium hexafluorophosphate, [4-(octyloxy)phenyl]phenyliodonium hexafluoroantimonate, triphenylsulfonium triplate, triphenylsulfonium hexafluorophosphate, triphenylsulfonium hexafluoroantimonate, triphenylsulfonium tetrakis(pentafluorophenyl)borate, 4,4′-bis[diphenylsulfonium]diphenylsulfide, bis-hexafluorophosphate, 4,4′-bis[di(β-hydroxyethoxy)phenylsulfonium]diphenylsulfide bis-hexafluoroantimonate, 4,4′-bis[di(β-hydroxyethoxy)(phenylsulfonium)]diphenyl sulfide bishexafluorophosphate, 7-[di(p-toyl)sulfonium]-2-isopropylthioxanthone hexafluorophosphate, 7-[di(p-toyl)sulfonio-2-isopropylthioxanthone hexafluoroantimonate, 7-[di(p-toyl)sulfonium]-2-isopropyl tetrakis(pentafluorophenyl)borate, phenylcarbonyl-4′-diphenylsulfonium diphenylsulfide hexafluorophosphate, phenylcarbonyl-4′-diphenylsulfonium diphenylsulfide hexafluoroantimonate, 4-tert-butylphenylcarbonyl-4′-diphenylsulfonium diphenylsulfide hexafluorophosphate, 4-tert-butylphenylcarbonyl-4′-diphenylsulfonium diphenylsulfide hexafluoroantimonate, 4-tert-butylphenylcarbonyl-4′-diphenylsulfonium diphenylsulfide tetrakis(pentafluorophenyl)borate, or diphenyl[4-(phenylthio)phenyl]sulfonium hexafluoroantimonate. A combination comprising at least one of the foregoing can be used. In an embodiment the photoacid generators may be used alone, or two or more may be used together. When the amount of the photoacid generator is less than 0.1 parts by weight, it is difficult to obtain sufficient photocurability. When it exceeds 10 parts by weight, photocurability may be impaired by light absorption of the photoacid generator.

In an embodiment, the photosensitive adhesive composition may include a coupling agent, which may increase adhesive strength. For example, the coupling agent may comprise a silane coupling agent, such as γ-methacryloyloxypropyltrimethoxysilane, vinyltriacetoxysilane, vinyltrimethoxysilane, γ-isocyanatopropyltriethoxysilane, γ-glycycloxypropyltrimethoxysilane, or β-3,4-epoxycyclohexylethylmethoxysilane, and the coupling agent may improve adhesive strength of the photosensitive adhesive composition.

Also, the photosensitive adhesive composition may include an organic or an inorganic filler. For instance, the photosensitive adhesive composition may comprise an inorganic filler, such as silica, alumina, boron nitride, titanium dioxide, glass, iron oxide, boron aluminum, a ceramic, or a rubber filler.

According to another exemplary embodiment, a patternable adhesive film is prepared using the photosensitive adhesive composition.

A base film of the patternable adhesive film may be polyethylene terephthalate (“PET”), but is not limited thereto.

The patternable adhesive film may be prepared by a commercially available method. For example, the patternable adhesive film may prepared by applying the adhesive composition onto a film having a certain thickness using a roll coater or bar coater, removing a solvent to provide a base layer, and then thermally laminating an upper protection film under pressure onto the base layer.

Since the resulting adhesive film provides excellent adhesion, patternability, and thermal resistance, the adhesive film may be used to provide a semiconductor package. That is, a pattern may be formed so that the adhesive film can be interposed between stacked dies to bond through electrodes using solders in a 3-dimensional stacked package technique. In addition, the adhesive film may be used in applications wherein it is desirable to have both the patternability and adhesiveness, for example in electronic materials, such as insulating coating materials, insulating layers, semiconductor materials, or electrode protection layers for thin-film transistor-liquid crystal displays (“TFT-LCDs”). Also, the adhesive film may be used for display materials, such as optical fibers or liquid-crystal alignment films, and transparent electrode films that comprise a conductive filler or comprise a surface coated with the conductive filler.

In another aspect, a semiconductor package having the adhesive film interposed between semiconductor wafers is provided. For example, the semiconductor package may be manufactured by applying the above disclosed adhesive composition on a semiconductor chips, or adhering an adhesive film, and then attaching a semiconductor chip to the adhesive film.

The semiconductor package may be a Through Silicon Via (“TSV”), in which semiconductor chips may be connected to one another by bonding through an electrode using a solder.

A die-bonding technique for stacking at least two layers, for example, four layers, eight layers, or sixteen layers, may be used for the semiconductor package. Therefore, integration limitations by the limited shrinkage of linewidths in memory fields may be overcome through a 3-dimensional stacking structure.

Furthermore, the above die-bonding technique may be applied not only to stacking of homogeneous dies in memory devices but also stacking of heterogeneous dies in non-memory devices.

Hereinafter, the exemplary embodiments will be disclosed in further detail with reference to Preparation Examples, Examples, Comparative Examples and Experimental Examples. The following examples are merely to explain the exemplary embodiments, and shall not limit the exemplary embodiments.

Specific specifications of components used in Examples and Comparative Examples are as follows.

1) Alkali soluble binder resin: ACA-Z251 and ACA-Z230 (DAICEL Chemical), a urethane oligomer, UXE-3024 (Nippon Kayaku), and a novolac oligomer, CCR-1291H (Nippon Kayaku).

2) Radical polymerizable acrylate monomer: An acrylic monomer, dipentaerythritol pentaacrylate (“DPPA”).

3) Epoxy resin: A triphenyl epoxy, EPPN-501H, a liquid epoxy, Bisphenol A diglycidyl ether (“BPA-G”), and an alkali soluble epoxy resin synthesized in the Examples.

4) Photopolymerization initiator: 1-Hydroxy-cyclohexyl-phenyl-ketone, Irgagure-369 (Ciba Specialty Chemicals).

5) Hardener: Xylene-modified phenol, MEH-7800.

### Preparative Example 1

### Preparation of N-(4-hydroxyphenyl) maleimide

A 53.94 gram (g) quantity of maleic anhydride and 125 milliliters (ml) of DMF are added to a 500-ml 3-neck flask. A 54.56 g quantity of 4-amino phenol is slowly added to the flask. Then, the resulting mixture is reacted at 25° C. for 3 hours to obtain an amic acid solution. A solution prepared by dissolving 28.5 g of phosphorus pentoxide and 12.5 ml of sulfuric acid in 175 ml of DMF is slowly added dropwise to the solution for 30 minutes. Then, the resulting mixture is further reacted at 70° C. for 3 hours. The solution is cooled to 25° C. and precipitated in ice water, and then the precipitate is washed several times with water to obtain a final product, N-(4-hydroxyphenyl) maleimide, which is then dried under a reduced pressure.

### Example 1

### Preparation of Epoxy Resin 1

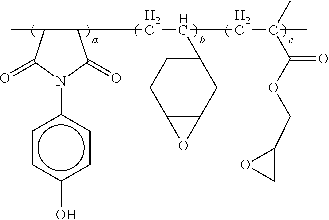

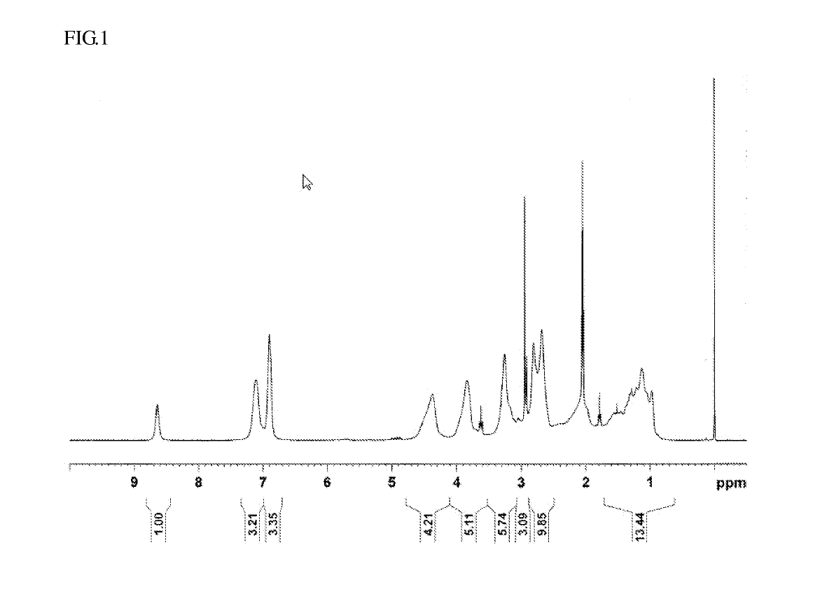

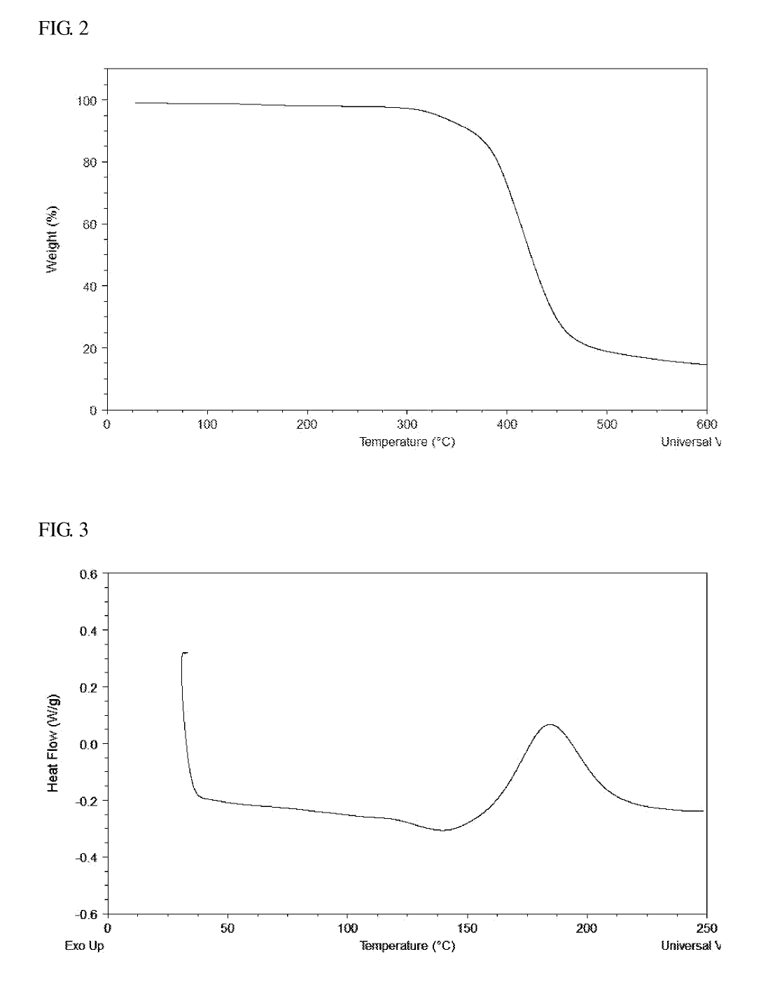

A 6.621 g (0.035 mole (mol)) quantity of N-(4-hydroxyphenyl) maleimide (“4-HPM”) prepared in Preparative Example 1, 4.3436 g (0.035 mol) of 4-vinyl-1-cyclohexene-1,2-epoxide (“VCHO”, Aldrich), 9.9512 g (0.07 mol) of glycidyl methacrylate (“GMA”) and 0.4626 g of azobisisobutyronitrile (“AIBN”) are dissolved in 31.56 g of PGMEA, put into a flask with nitrogen for 30 minutes, and then polymerized at 65° C. for 6 hours to synthesize an epoxy resin having a Concentration of 40% by weight in PGMEA. Gel permeation chromatography (“GPC”) analysis shows that the epoxy resin has a weight average molecular weight (Mw) of 20155 g/mol and a number average molecular weight (Mn) of 5417 g/mol. The NMR results show that a:b:c=1:0.856:1.875. From these results, an acid value and an epoxy equivalent weight (“EEW”) may be calculated to be 100 mgKOH/g and 205 g/eq, respectively. The NMR, TGA, and DSC results of the prepared epoxy resin are shown in FIGS. 1 to 3.

### Example 2

### Preparation of Epoxy Resin 2

An epoxy resin is prepared by the same method as in Example 1, except that AIBN is added at a content of 10 mol %, based on the total monomer content, to provide an epoxy resin having a concentration of 35% by weight in PGMEA. GPC analysis shows that the epoxy resin has Mw of 17276 g/mol and Mn of 6094 g/mol.

### Example 3

### Preparation of Epoxy Resin 3

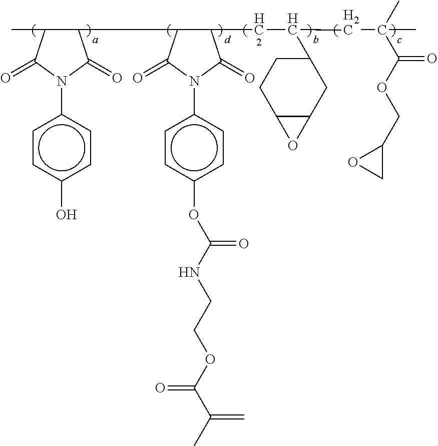

A 20 g quantity of the polymer prepared in Example 2 and 0.63 g (0.004 mol) of isocyanatoethyl methacrylate are put into a flask, and addition-reacted at 60° C. for 6 hours to prepare an epoxy resin having a concentration of 37% by weight in PGMEA. GPC analysis shows that the epoxy resin has Mw of 22562 g/mol and Mn of 6722 g/mol.

### Example 4

### Preparation of Epoxy Resin 4

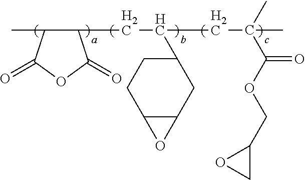

A 19.612 g (0.2 mol) quantity of maleic anhydride (“MA”), 24.836 g (0.2 mol) of 4-vinyl-1-cyclohexene-1,2-epoxide (“VCHO”, Aldrich), 28.432 g (0.2 mol) of glycidyl methacrylate (“GMA”), and 4.93 g (0.03 mol, 5 mol %) of AIBN are dissolved in 109.46 g of PGMEA, put into a flask with nitrogen for 30 minutes, and then polymerized at 65° C. for 6 hours to synthesize an epoxy resin 4 having a solution concentration of 40% by weight in PGMEA. GPC analysis shows that the epoxy resin has Mw of 14965 g/mol and Mn of 6049 g/mol.

### Example 5

### Preparation of Epoxy Resin 5

An epoxy resin is prepared by the same method as in Example 4, except that AIBN is added at a content of 10 mol %, based on the total monomer content to provide an epoxy resin having a concentration of 35% by weight in PGMEA. The GPC results show that the epoxy resin has Mw of 12772 g/mol and Mn of 4553 g/mol.

### Example 6

### Preparation of Epoxy Resin 6

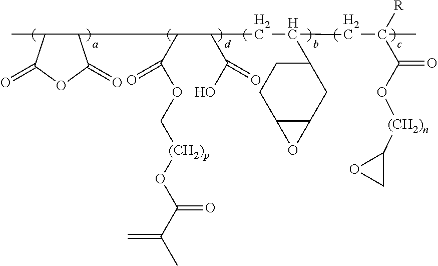

A 13 g (0.1 mol) quantity of 2-hydroxyethyl methacrylate, 0.75 g of triphenyl phosphine, 0.28 g of a thermal polymerization inhibitor, MEHQ, and 19.5 g of PGMEA are added to 91 g of a solution of the epoxy resin 4 prepared in Example 4. Then, a reaction is performed at 100° C. for 12 hours under an air atmosphere to synthesize an epoxy resin 5 into which an unsaturated polymerizable group, an acrylic group, and a carboxylic acid, are introduced, to provide an epoxy resin having a solution concentration of 40% by weight in PGMEA.

### Example 7

### Preparation of Epoxy Resin 7

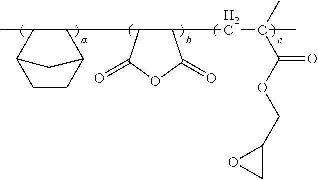

A 49.03 g (0.5 mol) quantity of maleic anhydride (“MA”), 47.08 g (0.5 mol) of norbornene (NB), 142.16 g (1.0 mol) of glycidyl methacrylate (“GMA”) and 6.57 g (0.04 mol, 2 mol %) of AIBN are dissolved in 357.4 g of PGMEA, put into a flask with nitrogen for 30 minutes, and then polymerized at 65° C. for 6 hours to synthesize an epoxy resin 7 to provide an epoxy resin having a solution concentration of 40% by weight in PGMEA. The GPC results show that the epoxy resin has Mw of 11095 g/mol and Mn of 7723 g/mol.

### Example 8

### Preparation of Epoxy Resin 8

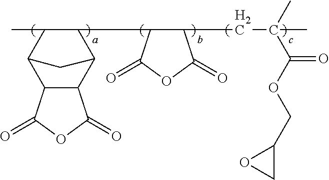

A 32.832 g (0.2 mol) quantity of 5-norbornene-2,3-dicarboxylic acid anhydride, 19.612 g (0.2 mol) of maleic anhydride, 28.432 g (0.2 mol) of glycidyl methacrylate (“GMA”) and 4.93 g (0.03 mol, 5 mol %) of AIBN are dissolved in 121.3 g of PGMEA, put into a flask with nitrogen for 30 minutes, and then polymerized at 65° C. for 6 hours to synthesize an epoxy resin 8.

### Examples 9 to 16

### Preparation of Adhesive Composition and Adhesive Film

Polyethylene terephthalate films are applied with a solution including the components and contents listed in the following Table 1 for Examples 9 to 16, and dried at 85° C. for 10 minutes in a dry oven to prepare negative photosensitive adhesive films having a thickness of 20 micrometers (μm).

### Comparative Examples 1 to 3

### Preparation of Adhesive Composition and Adhesive Film

Adhesive films are prepared by the same method as in Examples 9 to 16, except that the solution includes the components and contents listed for Comparative Examples 1 to 3 in Table 1.

### Experimental Example

### Measurement of Physical Properties of Adhesive Film

The adhesive films prepared in Examples and Comparative Examples are evaluated for pattern formability and adhesive force. The results are listed in the following Table 1.

### Pattern Formability

The adhesive film prepared in Example 1 is laminated on a wafer at a temperature of 65° C. using a roller, prebaked at 100° C. for 2 minutes, and irradiated with a UV light at an exposure dose of 1000 milliJoules (mJ) at a wavelength of 365 nanometers (nm) (e.g., i-line) using a negative-type photomask having a pitch of 40 μm and an open critical dimension (“CD”) of 20 μm, which corresponds to those of through electrodes, to photocure an exposure portion. Then, the wafer is postbaked at 100° C. for 2 minutes again, developed with an alkali developing solution of 2.38% by weight of tetramethylammonium hydroxide (“TMAH”) at room temperature, rinsed with distilled water, and then dried to obtain a desired pattern, which is observed with an optical microscope. When a pattern is precisely formed, the result is designated as ◯. And, when a pattern is not formed, the result is designated as X.

### Measurement of Shear Bond Strength (e.g., Adhesive Force)

A wafer having a PAF (“patternable adhesive film”) pattern formed on a top surface thereof is sawed into dies of the dimensions 5 mm×5 mm. The top surface with the PAF pattern is bonded to a polished surface of a bare die at 260° C. for 10 seconds under a pressure of 1 kilograms-force (kgf) using a die-bonding machine, and then post-baked at 175° C. for 2 hours. An adhesive force is measured in a die shear mode at a shear rate of 100 μm/sec at 250° C. The results are listed in Table 1.

TABLE 1

| | Materials | | | | | | | | | Comparative | | |
|---|---|---|---|---|---|---|---|---|---|---|---|---|
| | (parts by | Examples | | | | | | | | Example | | |
| | weight) | 9 | 10 | 11 | 12 | 13 | 14 | 15 | 16 | 1 | 2 | 3 |
| Binder resins | ACA-Z251 | — | — | — | 25 | 25 | 20 | 20 | 20 | 25 | 25 | 25 |
| | ACA-Z230 | 30 | 25 | 20 | — | — | — | — | — | — | — | — |
| Acrylate-based | UXE-3024 | 10 | 5 | 5 | 10 | 5 | 5 | 5 | — | 5 | 5 | 5 |
| Monomer | CCR-1291H | 30 | 25 | 30 | 30 | 25 | 30 | 30 | 30 | 30 | 30 | 30 |
| | DPPA | 5 | 5 | 5 | 5 | 5 | 5 | 5 | 5 | 5 | 5 | 5 |
| Epoxy resins | EPPN-501H | 5 | — | 5 | 10 | — | 5 | 10 | 10 | — | 10 | 20 |
| | BPA-G | — | — | 15 | — | 20 | 15 | 10 | 15 | — | 20 | 10 |
| | Example 2 | 20 | 20 | 20 | 20 | 20 | 20 | 20 | 20 | — | — | — |
| Hardener | MEH-7800 | — | — | — | — | — | — | — | — | 5 | 5 | 5 |
| Photo- | Irgacure | 3 | 3 | 3 | 3 | 3 | 3 | 3 | 3 | 3 | 3 | 3 |
| polymerization | 369 | | | | | | | | | | | |
| initiator | | | | | | | | | | | | |

| | | | | | | | | | | | |
|---|---|---|---|---|---|---|---|---|---|---|---|
| Pattern formability | ◯ | ◯ | ◯ | ◯ | ◯ | ◯ | ◯ | ◯ | ◯ | X | X |
| (40/20, μm) (pitch/open CD) | | | | | | | | | | | |
| Shear bond strength | 3.84 | 4.09 | 6.70 | 7.77 | 4.09 | 6.80 | 6.35 | 8.03 | 1.9 | 4.6 | 6.79 |
| (kgf/25 mm²) @ 250° C. | | | | | | | | | | | |

As shown in Table 1, it is seen that the patternable adhesive films including the alkali soluble epoxy resin prepared in Examples 9 to 16 have good pattern formability and excellent shear bond strength (e.g., adhesive force).

The invention should not be construed as being limited to the embodiments set forth herein. Rather, these embodiments are provided so that this disclosure will be thorough and complete and will fully convey the disclosed embodiments to one of ordinary skill in the art.

While the invention has been particularly shown and described with reference to embodiments thereof, it will be understood by those of ordinary skill in the art that various changes in form and details may be made therein without departing from the spirit or scope of the present invention as defined by the following claims.

What is claimed is:

1. A photosensitive adhesive composition comprising:
an alkali soluble epoxy resin,
an alkali soluble binder resin,
a radical polymerizable (meth)acrylate monomer,
a photopolymerization initiator, and
a solvent,
wherein the alkali soluble epoxy resin comprises a copolymer of
at least one selected from a maleimide compound, and a maleic anhydride compound, and
at least one selected from a (meth)acrylate monomer comprising an epoxy group, and a vinyl monomer comprising an epoxy group.

2. The photosensitive adhesive composition of claim 1, wherein the alkali soluble epoxy resin is a copolymer of
at least one C₄ to C₂₀ cycloalkene compound, which is selected from a maleimide compound and a maleic anhydride compound, and
at least one selected from a (meth)acrylate monomer comprising an epoxy group, and a vinyl monomer comprising an epoxy group.

3. The photosensitive adhesive composition of claim 1, wherein a nitrogen of the maleimide compound is substituted with a phenyl group substituted with at least one selected from a carboxyl group and a hydroxyl group.

4. The photosensitive adhesive composition of claim 1,
wherein the alkali soluble epoxy resin comprises a reaction product of the maleimide compound and a (meth)acrylate monomer comprising an isocyanate group and at least one (meth)acryloyl group.

5. The photosensitive adhesive composition of claim 1,
wherein the maleic anhydride compound is maleic anhydride, or a maleic anhydride to which at least one C₄ to C₂₀ cycloalkene is fused.

6. The photosensitive adhesive composition of claim 1,
wherein the alkali soluble epoxy resin comprises a reaction product of the maleic anhydride compound and a (meth)acrylate monomer comprising a hydroxyl group.

7. The photosensitive adhesive composition of claim 6,
wherein the (meth)acrylate monomer comprising a hydroxyl group has a structure represented by the following Formula 4: 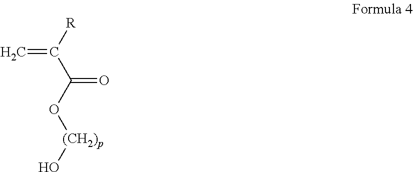
wherein p is an integer of 1 to 10, and R is hydrogen or a methyl group.

8. The photosensitive adhesive composition of claim 2,
wherein the C₄ to C₂₀ cycloalkene comprises a double bond within the cyclic moiety, or the cycloalkene comprises a vinyl group.

9. The photosensitive adhesive composition of claim 2,
wherein the C₄ to C₂₀ cycloalkene is selected from 2-norbornene, 5-vinyl-2-norbornene, bicyclo[2.2.1]hepta-2,5-diene, dicyclopentadiene, and a cyclohexene compound.

10. The photosensitive adhesive composition of claim 1,
wherein the vinyl monomer comprising an epoxy group is selected from 4-vinyl-1-cyclohexene-1,2-epoxide, allyl glycidyl ether, and cyclohexane-1,2-epoxide-substituted norbornene.

11. The photosensitive adhesive composition of claim 1,
wherein the (meth)acrylate monomer comprising an epoxy group includes a structure represented by the following Formula 5: 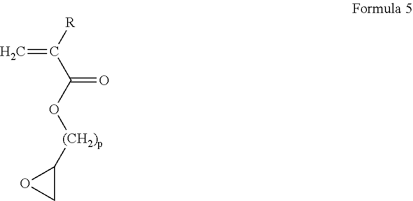
wherein R is hydrogen or methyl, and n is integer of 1 to 10.

12. The photosensitive adhesive composition of claim 1,
wherein the alkali soluble epoxy resin comprises a structure represented by the following Formula 6: 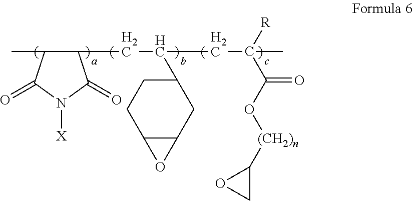
wherein X is a carboxyl group, or a phenyl group which is substituted with at least one substituent selected from a carboxyl group and a hydroxyl group,
R is hydrogen or methyl,
n is an integer of 1 to 10, and
a, b and c represent a mole fraction of each respective unit, a+b+c=1, a mole fraction ratio a:b:c is 0.1 to 0.5:0 to 0.9:0 to 0.9, b+c>0, and the a, b, and c units are arranged in any order.

13. The photosensitive adhesive composition of claim 1,
wherein the alkali soluble epoxy resin includes a structure represented by the following Formula 7: 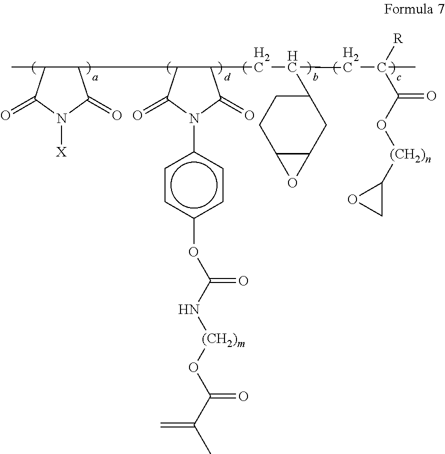
wherein X is a carboxyl group, or a phenyl group which is substituted with at least one substituent selected from a carboxyl group and a hydroxyl group,
R is hydrogen or methyl,
each n and m is independently an integer of 1 to 10, and
a, b, c, and d represent a mole fraction of each respective unit, a+b+c+d=1, a mole fraction ratio a:b:c:d is 0 to 0.49:0 to 0.9:0 to 0.9:0.01 to 0.5, b+c>0, and the a, b, c, and d units are arranged in any order.

14. The photosensitive adhesive composition of claim 1,
wherein the epoxy resin includes a structure represented by the following Formula 10: 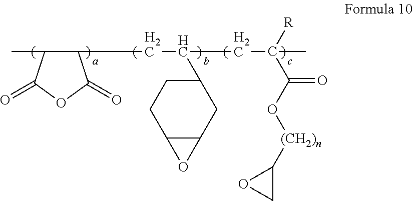
wherein, R is hydrogen or methyl,
n is an integer of 1 to 10, and
a, b and c represent a mole fraction of each respective unit, a+b+c=1, a mole fraction ratio a:b:c is 0.1 to 0.5:0 to 0.9:0 to 0.9, b+c>0, and the a, b, and c units can be arranged in any order.

15. The photosensitive adhesive composition of claim 1,
wherein the epoxy resin includes a structure represented by the following Formula 11: 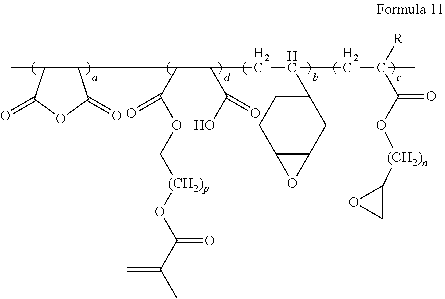
wherein, R is hydrogen or methyl,
each n and p is independently an integer of 1 to 10, and
a, b, c and d represent a mole fraction of each respective unit, a+b+c+d=1, a mole fraction ratio a:b:c:d is 0 to 0.49:0 to 0.9:0 to 0.9:0.01 to 0.5, b+c>0, and the a, b, c, and d units are arranged in any order.

16. The photosensitive adhesive composition of claim 1,
wherein the alkali soluble binder resin comprises at least one selected from a novolac acrylate oligomer comprising a carboxyl group and an acryloyl group, a urethane acrylate oligomer comprising a carboxyl group and an acryloyl group, and an acrylate polymer comprising a carboxyl group and an acryloyl group, and
wherein the alkali soluble binder resin has a glass transition temperature of about 50° C. or higher.

17. The photosensitive adhesive composition of claim 1,
further comprising at least one selected from a multifunctional epoxy resin having a softening point of about 150° C. or less, and a multifunctional epoxy resin which is a liquid at about 25° C.

18. The photosensitive adhesive composition of claim 1,
further comprising at least one selected from a curing agent, a curing accelerator, a catalyst, a photo-acid generator, a coupling agent, and a filler.

19. A patternable adhesive film comprising a product of the photosensitive adhesive composition according to claim 1.

20. A through-silicon-via-type semiconductor package comprising the patternable adhesive film of claim 19 interposed between a first and a second semiconductor wafer.
